(19) United States
(12) Patent Application Publication
(10) Pub. No.: US 2006/0270224 A1
(43) Pub. Date: Nov. 30, 2006

(54) Methods for forming metal-silicon layer using a silicon cap layer

(76) Inventors: Seung-Chul Song, Austin, TX (US); Byung Hun Lee, Austin, TX (US); Zhibo Zhang, Plano, TX (US)

Correspondence Address: FULBRIGHT & JAWORSKI L.L.P., 600 CONGRESS AVE., SUITE 2400, AUSTIN, TX, 78701, US

(21) Appl. No.: 11/349,737

(22) Filed: Feb. 8, 2006

Related U.S. Application Data
(60) Provisional application No. 60/650,989, filed on Feb. 8, 2005.

(51) Int. Cl. H01L 21/44

(52) U.S. Cl. 438/682

(57) ABSTRACT

Techniques for forming a layer of MetalₓSi_{y} without overly depleting the source/drain region of a silicon substrate are disclosed. In one respect, a cobalt layer is formed on a silicon-containing substrate. A metal layer is formed on the cobalt layer. A CoSi layer is formed through heating. Un-reacted cobalt and metal from the cobalt and metal layers are removed. A silicon cap layer is formed on the CoSi layer. A CoSi₂ layer is then formed through heating, the CoSi₂ layer being formed upward into the silicon cap layer.

This patent application claims priority to, and incorporates by reference in its entirety, U.S. provisional patent application Ser. No. 60/650,989 filed on Feb. 8, 2005, entitled, “Forming CoSi₂ Using a Si Cap Layer.”

### BACKGROUND OF THE INVENTION

1. Field of the Invention

The present invention relates generally to the field of semiconductor processing and more particularly, it concerns the silicidation process to form, for example, a CoSi₂ layer within and on a semiconductor surface.

2. Description of Related Art

For certain semiconductor processes, it is beneficial to create a thick metal-silicon layer (Metalₓ,Si_{y}) known as a silicide, such as a CoSi₂ layer on a device surface to reduce sheet resistance and to provide etch stopping capability during contact etch and/or sputter clean. Even though a thick layer of CoSi₂ is beneficial, it also must be thin enough not to intrude too deeply into a source and drain junction area. If the CoSi₂ is too close to the depletion width of the source and drain junction, high junction leakage current will most likely result.

As the progress of technology in this field requires shallower and shallower junctions in order to suppress the short channel effect, CoSi₂ thickness should be scaled down accordingly. On the other hand, if a CoSi₂ layer is too thin, sheet resistance increases, and the layer may be broken-through during contact etch. If the layer is broken-through during contact etch, resistance increases dramatically, ultimately causing device malfunction. Specifically, this contact resistance may cause degraded output saturation current, affecting the on/off ratio of a MOSFET, which may cause a loss of switching capability.

Using conventional technology, CoSi₂ often intrudes too deeply into a source and drain region. Such intrusion may cause a high junction leakage current, which may increase off-state current. Therefore, and in view of the importance of proper CoSi₂ formation as semiconductor technology advances, there is a need for improvements in the manufacture and positioning of CoSi₂ layers to protect devices without limiting their functionality.

Referenced shortcomings of conventional technology mentioned above are not intended to be exhaustive, but rather are among many that tend to impair the effectiveness of previously known techniques concerning the fabrication of MetalₓSi_{y} layers. Other noteworthy problems may also exist; however, those mentioned here are sufficient to demonstrate that a need exists for the techniques described and claimed here.

### SUMMARY OF THE INVENTION

In one respect, at least a portion of a MetalₓSi_{y} combination, such as, without limitation, a CoSi₂ layer may be formed upward instead of the conventional technique of forming it downward and closer to the source and drain junction. As described more below, this upward growth is generally made possible by applying a silicon cap layer to a layer of CoSi that forms within and on a silicon substrate, followed by a heating step (e.g., a rapid thermal anneal) to form the CoSi₂ layer. The CoSi₂ layer forms upward into the silicon cap, as silicon is provided from the overlying silicon cap layer to convert CoSi to CoSi₂.

By producing a layer of CoSi₂ partially above the substrate rather than completely within the substrate, more of the substrate is available for device functionality. As such, improved device performance and reliability result. Techniques of this disclosure therefore provide for the benefits of having a CoSi₂ layer without some of the significant drawbacks associated with conventional methods.

In one embodiment, the invention involves a method for forming a CoSi₂ layer. A cobalt layer is formed on a silicon-containing substrate. A metal layer is formed on the cobalt layer. A CoSi layer is formed through heating. Un-reacted cobalt and metal are removed from the cobalt and metal layers. A silicon cap layer is formed on the CoSi layer. A CoSi₂ layer is formed through heating, the CoSi₂ layer being formed upward into the silicon cap layer. The cobalt layer may be about 100 521 thick. The metal layer may be about 200 Å thick. The silicon cap layer may be about 300 Å thick. The metal layer may include titanium. The metal layer may include titanium nitride. The method may also include removing un-reacted silicon from the silicon cap layer. The CoSi layer may be formed by a rapid thermal anneal at about 500° C. for about 60 seconds. The CoSi₂ layer may be formed by a rapid thermal anneal at about 800° C. for about 60 seconds.

The terms “a” and “an” are defined as one or more unless this disclosure explicitly requires otherwise.

The term “substantially,” “about,” and its variations are defined as being largely but not necessarily wholly what is specified as understood by one of ordinary skill in the art, and in one-non and in one non-limiting embodiment the substantially refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain non-limiting aspects of the present invention. Illustrated embodiments should not be interpreted to limit the scope of the claims, as they are examples only.

FIG. 1 shows a gate structure with a layer of cobalt (Co) formed on its surface, in accordance to embodiments of the present disclosure.

FIG. 2 shows the structure depicted in FIG. 1 with a layer of titanium nitride (TiN) formed on the layer of cobalt, in accordance to embodiments of the present disclosure.

FIG. 3 shows the structure depicted in FIG. 2 after a rapid thermal anneal (RTA) has been performed, in accordance to embodiments of the present disclosure.

FIG. 4 shows the structure depicted in FIG. 3 after un-reacted TiN and Co are removed from the surface of the structure, in accordance to embodiments of the present disclosure.

FIG. 5 shows the structure depicted in FIG. 4 after a second RTA is performed resulting in a layer of CoSi₂ as taught by the prior art.

FIG. 6 shows the structure depicted in FIG. 4 after a silicon (Si) cap layer is formed on the surface of the structure, in accordance to embodiments of the present disclosure.

FIG. 7 shows the structure depicted in FIG. 6 after a second rapid thermal anneal is performed resulting in a layer of CoSi₂ that forms upwards, in accordance to embodiments of the present disclosure.

FIG. 8 shows the structure in FIG. 7 after un-reacted silicon is removed from the structure, in accordance to embodiments of the present disclosure.

FIG. 9 shows a method for forming a MetalₓSi_{y} layer, in accordance to embodiments of the present disclosure.

FIG. 10 shows layers of a wafer.

FIG. 11 shows the wafer of FIG. 10 after conventional techniques for forming a CoSi₂ layer.

FIG. 12 shows the wafer of FIG. 10 using techniques of the present disclosure for forming a CoSi₂ layer.

### DETAILED DESCRIPTION OF THE INVENTION

The disclosure and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

Silicidation is process in combining metals (refractory or noble) with silicon using a heat treatment to create a MetalₓSi_{y} combination. In general, a MetalₓSi_{y} combination is formed by depositing a metal over a polysilicon layer and a substrate containing silicon, followed by a two-step anneal process. Many benefits of the silicidation process include the reduced resistivity provided by certain metal/silicon compounds. Silicides have been used for many years in the fabrication industry to circumvent the high resistivity seen when contacting metal to polysilicon gates and source/drain regions of conventional MOSFET (Metal-Oxide Semiconductor Field Effect Transistor) structures. Different metals may be used to create silicides based on their properties such as processing temperature, dry and wet etch compatibilities, resistivity, dominant diffuser species, and the like.

Some specific applications of suicides include providing lower resistance on polysilicon gates, leading to a decrease in electrical response delay (e.g., critical for long gate lines). Silicides also enable bridging of dual-gate CMOS (Complementary Metal-Oxide Semiconductor) devices, and reduce contact resistance at CMOS source and drain structures. In some embodiments, silicides may be metallic, superconducting, or semiconducting, which makes them suitable for a variety of applications as active components, interconnects or nanoelectrodes for solid state or molecular electronic systems. Examples of metals that can be alloyed with silicon include, without limitation, titanium, cobalt, molybdenum, iron, platinum, niobium, hafnium, vanadium, zirconium, chromium, calcium, nickel, tantalum, tungsten, or any combination of the above.

The present disclosure provides techniques for fabricating a MetalₓSi_{y} combination. In one non-limiting example, a CoSi₂ layer may be fabricated using a thin (about 100 Å to about 500 Å) silicon cap layer deposited onto a CoSi layer after selective removal of un-reacted cobalt using techniques known in the art. Conversion from CoSi to CoSi₂ takes top silicon (i.e., silicon from the silicon cap layer) instead of consuming significant source/drain silicon. In this way, CoSi₂ encroachment into the source/drain junction region may be kept shallow (e.g., about 250 Å), and another CoSi₂ region may be formed (e.g., about 200 Å) using the top silicon cap layer. After a rapid thermal anneal (RTA) process that forms the CoSi₂, un-reacted silicon from the silicon cap may be selectively wet etched or otherwise removed. When compared to conventional techniques, the final CoSi₂ thickness may be the same, but the distance from the source/drain junction may be much reduced, allowing for shallower junction formation.

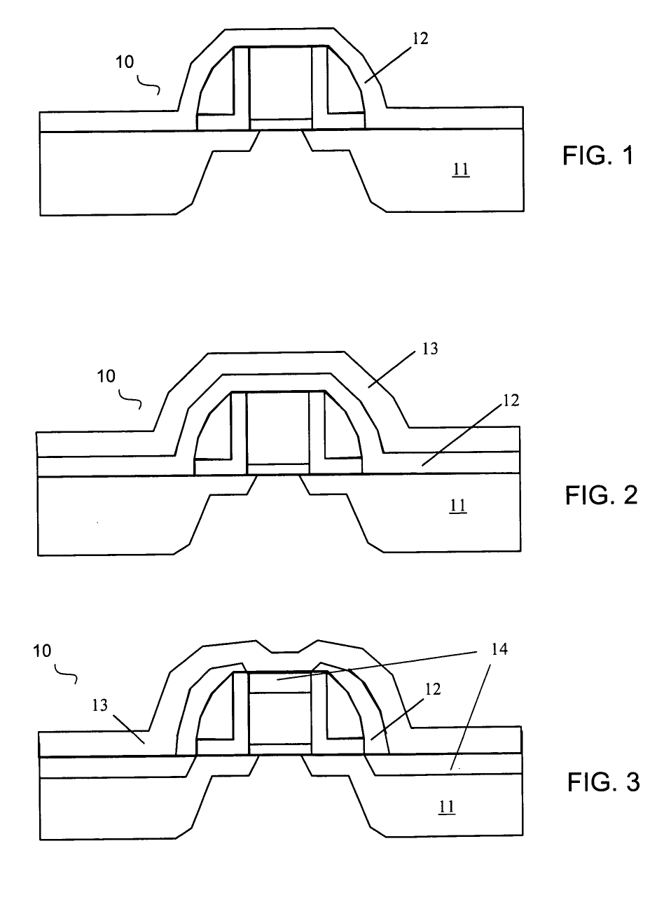

FIG. 1 shows an example of CMOS device structure 10 that may be used to form a CoSi₂ layer using a silicon (Si) cap layer according to embodiments of the disclosure. FIG. 1 shows substrate 11, which in one embodiment, may be silicon but alternatively, can be any other material known or found to be suitable for substrates. A cobalt (Co) layer 12 may be deposited onto substrate 11. The deposition of cobalt layer 12 may be achieved using methods that are well-known in the art. One method for forming the cobalt layer 12 is conventional blanket deposition, in particular sputtering, but any known or discovered method can be utilized to form a this layer on structure 10. Alternatively, a chemical vapor metal deposition may be used.

The thickness of the cobalt layer may vary based on the desired thickness of the final layer of CoSi₂, where the cobalt thickness depends on the depth of the source and drain junction. In one embodiment a cobalt thickness range between about 80 Å and about 120 Å would be appropriate for 90 nm technology. For example, a metal layer of about 100 Å thick may be used. The cobalt thickness may scale as source and drain junction depth scale with semiconductor planning roadmaps. Structure 10 exhibits a deep source and drain region, but it will be understood by those having ordinary skill in the art that the techniques of this disclosure may be applied to various other semiconductor configurations.

FIG. 2 shows a titanium nitride (TiN) layer 13 deposited on cobalt layer 12 using a variety of methods known in the art, including but not limited to, a chemical vapor deposition (CVD) technique. The thickness of the layer of metal used at this stage can vary. In one respect, the TiN layer aids in preventing oxidation of cobalt layer 12 where a thickness range of between about 150 Å and about 300 Å may be used to achieve that effect. In one embodiment, a layer of TiN of about 200 Å thick may be used.

It is noted that alternative metal layers may be deposited on cobalt layer 12. For example, a titanium (Ti) layer or other suitable layer may be deposited.

FIG. 3 shows the resultant structure after performing rapid thermal anneal (RTA) process on structure 10 of FIG. 2. The annealing process may vary depending on, for example, the choice of metal deposited on cobalt layer 12 in FIG. 2, reasons related to the structure 10, or other external factors. These factors are well known in the art of semiconductor manufacture. In one embodiment, the RTA process may be performed at a temperature of about 500° C. for about 60 seconds. The RTA step results in the formation of CoSi layer 14, without substantial production of CoSi₂. CoSi layer 14 is formed generally downward, into upper portions of substrate 11, as shown in FIG. 3. The transformation yielding CoSi layer 14 requires about 180 Å of substrate (e.g., Si) consumption and leaves a total CoSi 14 thickness of about 250 Å. These thicknesses may vary widely depending on processing parameters. The required silicon thickness for the transformation depends on initial cobalt thickness. For cobalt thickness of between about 80 Å and about 120 Å, about 150 Å to about 220 Å silicon may be needed for the transformation. The resultant CoSi thickness would range about 220 Å to about 310 Å.

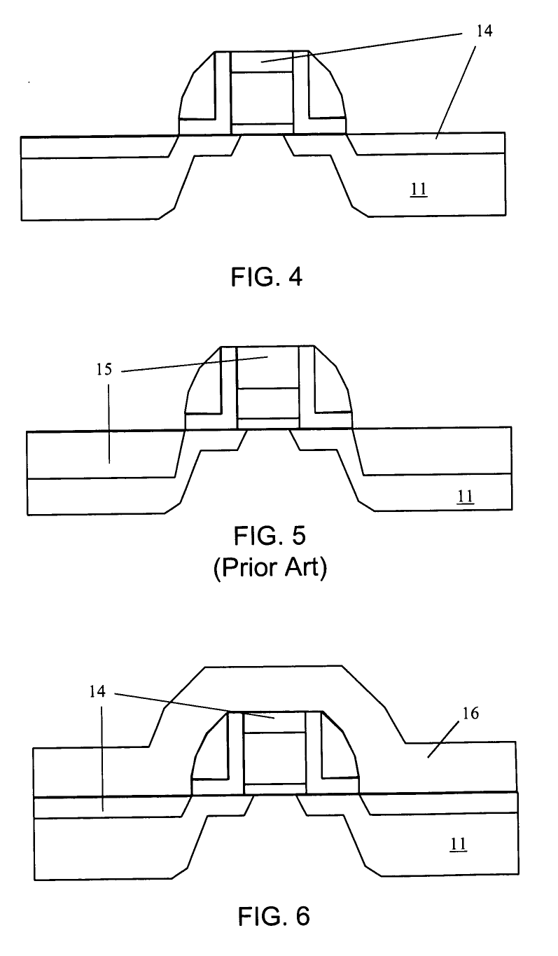

FIG. 4 shows the result of structure 10 after the TiN layer 13 and cobalt layer 12 are removed. This step may result in a structure similar to structure 10 in FIG. 1 with some of substrate 11 converted into CoSi layer 14. There are many techniques known in the art for selectively etching TiN layer 13 and Co layer 12 without substantially affecting CoSi layer 14. For example, in one embodiment, a selective wet etch may be used. However, other etching techniques or removal process may be used to remove layers 12 and 13.

FIG. 5 shows a prior art technique for forming CoSi₂ from the particular structure shown in FIG. 4. FIG. 5 is included simply to contrast prior art techniques from embodiments of the present disclosure. In FIG. 5, a second RTA step is applied to convert CoSi layer 14 into a deeper CoSi₂ layer 15. CoSi₂ layer 15 is formed generally downward, further into the source and drain region as shown by FIG. 5, where CoSi₂ layer 15 is close to the junction area. In a typical process, the second RTA step requires an additional 180 Å of silicon from substrate 11 and yields a CoSi₂ layer 15 having a total thickness of about 350-650 Å. These thicknesses are examples only, and those having ordinary skill in the art will recognize that the thicknesses are highly influenced by the particular processing steps performed during the second RTA as well as the conditions of prior processing steps.

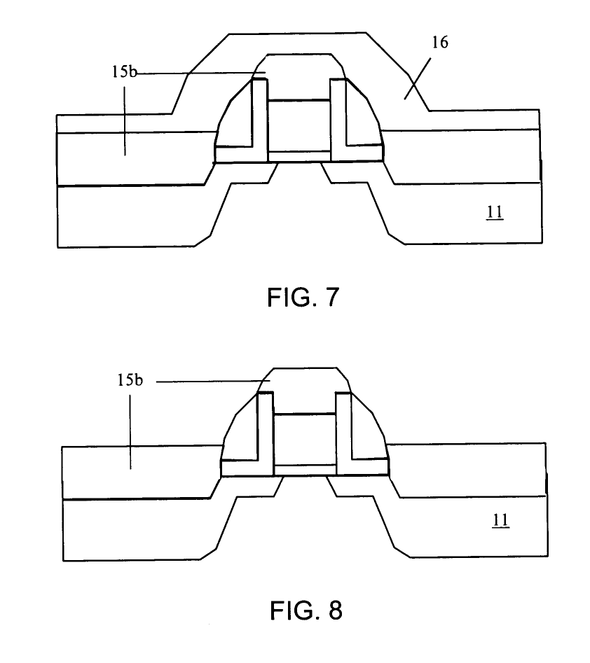

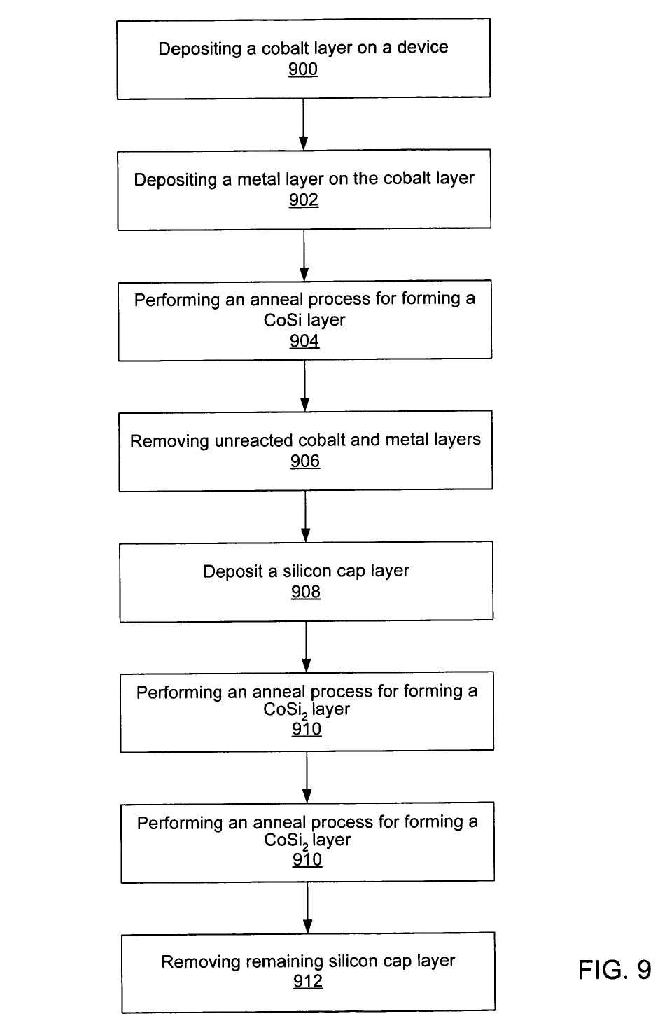

FIG. 6 is in accordance with embodiments of the present disclosure and contrasts the techniques shown in FIG. 5. The technique of FIG. 6 (along with FIGS. 7-8, discussed below) produces a CoSi₂ layer that generally forms upward so as to not intrude unduly into the source and drain region. In FIG. 6, a silicon cap layer 16 may be deposited on the structure 10 depicted in FIG. 4. It is noted that silicon cap layer 16 may include materials other than silicon as long as it is suitable for aiding in the formation of CoSi₂ from CoSi, and more particularly, for generally upward formation of CoSi₂. In one embodiment, silicon cap layer 16 may be formed using a variety of methods known in the art and may be about 300 Å in thickness, although thinner or thicker layers may be used according to particular application.

In FIG. 7, a second RTA step is performed to convert CoSi layer 14 into CoSi₂ layer 15b. The presence of silicon cap 16 reduces the amount of silicon consumed in substrate 11 during the RTA process. Instead, the formation CoSi₂ layer 14b consumes upper silicon cap 16, which in turn assures generally upward formation of CoSi₂ layer 15b. Therefore, more of the source and drain region is available for functional purposes, while still providing the benefits of a thick layer of CoSi₂.

In one embodiment, the second RTA step may be performed at about 800° C. for about 60 seconds, although in other embodiments, different parameters may be chosen for converting CoSi into CoSi₂. As is illustrated in FIG. 7, the techniques of this disclosure may provide for a CoSi₂ layer 15b with a similar thickness as compared to conventional methods, without the drawbacks of the conventional method as shown in FIG. 5. In one embodiment, the total CoSi₂ thickness may range from about 350 Å to about 650 Å.

Following the second RTA step, there may be residual portions of silicon cap 16 remaining on CoSi₂ layer 15b, as illustrated in FIG. 7. The residual portions may be removed with additional processing known in the art, such as etching techniques, resulting in a structure shown in FIG. 8. In one embodiment, residual cap layer 16 may be selectively wet etched. As shown by FIG. 8, the source and drain region is larger, which may provide for, among other things, improved device performance. Additionally, CoSi₂ layer 15b may be in different areas of device 10 as compared to the resultant structure from traditional method (e.g., layer 15 of FIG. 5).

In some embodiments, the silicon cap 16 is too thin to leave a residue. However, device performance benefits because any silicon that is consumed from silicon cap 16 that would have otherwise been consumed from substrate 11 and correspondingly reduce the depth of the source and drain region.

### EXAMPLE

The following examples are included to demonstrate a specific embodiment of this disclosure. It should be appreciated by those of ordinary skill in the art that the techniques disclosed in the example can be considered to constitute specific modes for its practice. However, those of ordinary skill in the art should, in light of the present disclosure, appreciate that many changes can be made in the specific embodiment and still obtain a like or similar result without departing from the spirit and scope of the invention.

Process Flow for Forming a CoSi₂ Layer Using a Silicon Cap Layer

An example implementation of this disclosure involves the following processing steps, as shown in FIG. 9. In step 900, a cobalt layer may be deposit on a substrate having a source and drain region, the cobalt layer having a thickness of about 100 Å. Next, in step 902, a metal layer may be deposited on the cobalt layer. In one embodiment, the metal layer may be a titanium layer, a titanium nitride layer, or the like having a thickness of about 200 Å. A first RTA at about 500° C. for about 60 seconds may be performed on the resultant structure after step 902, forming a CoSi layer at the poly and active areas (step 904). Next, the un-reacted cobalt and metal layer may be removed. In one embodiment, a selective wet etch process may be used, resulting in a substantially CoSi layer on the substrate (step 906).

In step 908, a silicon cap layer may be deposited onto the CoSi layer. In one embodiment, the silicon cap layer may have a thickness of about 300 Å, although varying thickness appropriate for the desired CoSi₂ layer may be used. Next, a second rapid thermal anneal process may be perform, converting the CoSi layer to a CoSi₂ layer (step 910). In one embodiment, the conversion utilizes the silicon cap layer, allowing for an upward formation and for substantially preserving the substrate. The RTA may be performed at 800° C. for about 60 seconds. Next, if any residual silicon from the silicon cap layer remains, a removal process is performed such as an etch process (step 912).

Process Flow for Forming a CoSi₂ Layer Using a Silicon Cap Layer

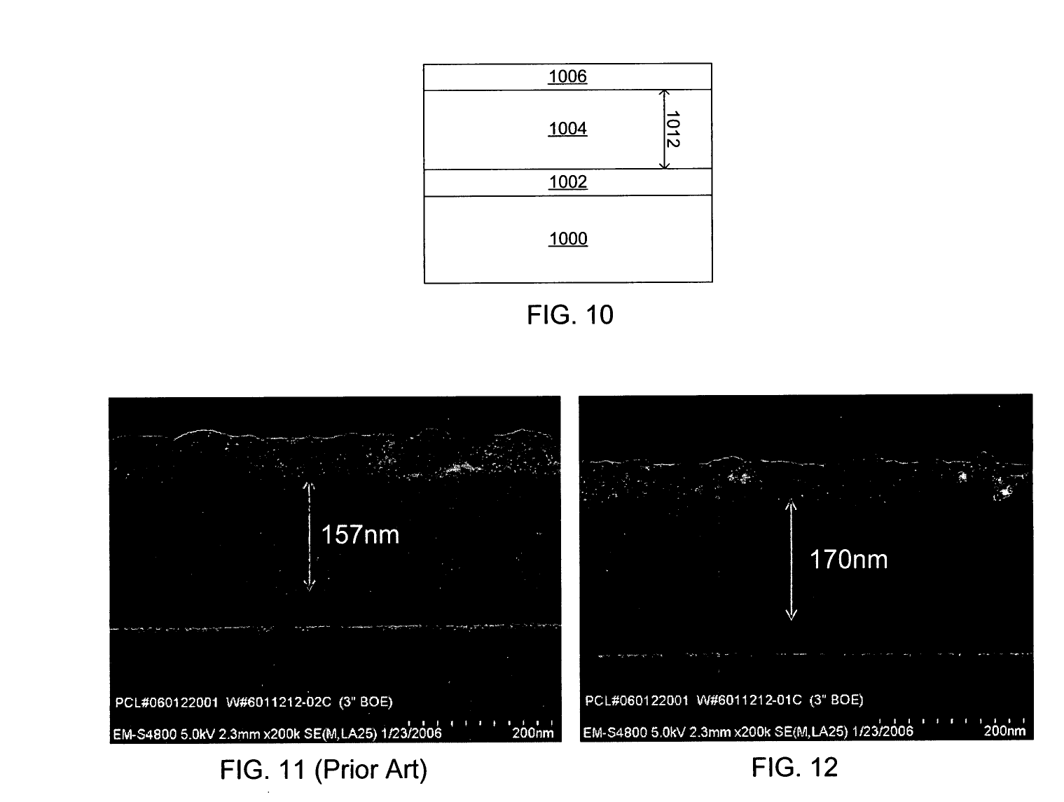

Referring to FIG. 10, a structure having silicon substrate 1000, Tetraethyl Orthosilicate layer (TEOS) 1002, polysilicon layer 1004, and silicide layer 1006 is used following first, conventional techniques and second, following techniques of the present disclosure (e.g., process flow shown in FIG. 9) to determine the effect of a silicon cap layer. In one respect, if silicide is formed upward when a silicon cap layer is used, the distance between the TEOS layer 1002 and the silicide layer 1006 (indicated by arrow 1012) should be larger. The process flow is outlined in Table 1 below, where Wafer 1 followed conventional techniques and Wafer 2 followed techniques of the present disclosure.

| | | | 100 Å | RTA | | | RTA | Remove | |
|---|---|---|---|---|---|---|---|---|---|
| | | | (Co)/ | 550° C. | | Silicon | 750° C. | Residual | SEM |
| | 500 Å | 2 kÅ | 200 Å | for | Co/TiN | Cap | for | Silicon | cross- |
| | TEOS | Polysilicon | (TiN) | 30 sec. | strip | 300 Å | 30 sec | Cap | section |
| Wafer 1 | X | X | X | X | X | | X | | X |
| Wafer 2 | X | X | X | X | X | X | X | X | X |

The results of Wafers 1 and 2 are shown in FIGS. 11 and 12, respectively. Wafer 2, using the 300 Å of a silicon cap layer, has about 130 Å more silicide than Wafer 1. The results show the silicide forms upward towards the cap, deterring the consumption of silicon substrate 1000.

While the disclosure has been particularly shown and described with respect to preferred embodiments, it will be understood by those of ordinary skill in the art that changes in forms and details my be made without departing from the spirit and scope of the present invention, and particularly the claims. It is therefore intended that the present disclosure is not limited to the exact forms and details described and illustrated, but fall within the scope of the appended claims, along with the equivalents of those claims.

For example, while the above provides non-limiting examples of a silicidation process for forming a CoSi₂ layer, the present disclosure provides techniques for other silicidation processes. For example, other metal layers may be used to form a MetalₓSi_{y} layer, where a silicon cap layer may be used to deter the consumption of silicon in some substrates. These metals may include, without limitation, titanium, cobalt, molybdenum, iron, platinum, niobium, hafnium, vanadium, zirconium, chromium, calcium, nickel, tantalum, tungsten, or any combination of the above. The resultant structure using techniques of this disclosure can provide, among other advantages, a shallow source/drain junction region and improved device performance.

1. A method for forming a CoSi₂ layer, comprising:
providing a silicon-containing substrate;
forming a cobalt layer on the silicon-containing substrate;
forming a metal layer on the cobalt layer;
forming a CoSi layer through heating on the silicon-containing substrate;
removing un-reacted cobalt and metal from the cobalt and metal layers;
forming a silicon cap layer on the CoSi layer; and
forming a CoSi₂ layer through heating, the CoSi₂ layer being formed upward into the silicon cap layer.

2. The method of claim 1, where the cobalt layer is about 100 Å thick.

3. The method of claim 1, where the metal layer is about 200 Å thick.

4. The method of claim 1, where the silicon cap layer is about 300 Å thick.

5. The method of claim 1, where the metal layer comprises titanium.

6. The method of claim 1, where the metal layer comprises titanium nitride.

7. The method of claim 1, further comprising removing un-reacted silicon from the silicon cap layer.

8. The method of claim 1, where the CoSi layer is formed by a rapid thermal anneal at about 500° C. to about 550° C. for about 30 to 60 seconds.

9. The method of claim 1, where the CoSi2 layer is formed by a rapid thermal anneal at about 750° C. to about 800° C. for about 30 to 60 seconds.

10. A method for forming a MetalₓSi_{y} layer comprising:
depositing a first metal for forming a first metal layer;
depositing a second metal on the first metal layer for forming a second metal layer;
annealing the first and second metal layer for forming a metal-silicon layer;
removing unreacted metals from the first and second metal layers;
depositing a silicon cap layer on the metal-silicon layer; and
annealing the metal-silicon layer for forming a MetalₓSi_{y} layer, the MetalₓSi_{y} layer being formed upward into the silicon cap layer.

11. The method of claim 1, the first and second metals comprising a refractory or noble metal.

12. The method of claim 10, the first and second metals comprising a compound metal.

13. The method of claim 1, where the step of annealing the first and second metal comprises a rapid thermal anneal at about 500° C. to about 550° C. for about 30 to 60 seconds.

14. The method of claim 1, where the step of annealing the metal-silicon layer comprises a rapid thermal anneal at about 750° C. to about 800° C. for about 30 to 60 seconds.
